(19) United States
(12) Patent Application Publication
(10) Pub. No.: US 2012/0142304 A1
(43) Pub. Date: Jun. 7, 2012

(54) Power Amplifiers for Wireless Systems

(76) Inventors: Ofir Degani, Haifa (IL); Ashoke Ravi, Hillsboro, OR (US); Hasnain Lakdawala, Beaverton, OR (US)

(21) Appl. No.: 12/958,503

(22) Filed: Dec. 2, 2010

(51) Int. Cl. H04B 1/16; H03F 1/00

(52) U.S. Cl. 455/343.1; 330/127

(57) ABSTRACT

A wireless transceiver may include a power amplifier that uses an envelope tracker. The envelope tracker may include stacked buck switching supply modulators, each having two different supply voltages. In one embodiment, the two different supply voltages are higher and lower supply voltages, which relaxes the voltage head room on the switching regulator and allows the use of thin gate fast transistors in some embodiments.

### BACKGROUND

This relates generally to wireless systems and, particularly, to power amplifiers for wireless systems.

Power amplifiers are an important element in wireless transceivers. Because they are one of the main power consumers in most wireless radio systems, power amplifiers are important in the design consideration of a radio system. In many cases, power consumption is an important design criteria for wireless systems, including those that are battery powered.

One known technique for controlling power consumption of wireless transceivers is envelope tracking used for signals with moderate peak to average power ratio, such as Enhanced Data Rates for GSM Evolution (EDGE) applications. In these signals, the power of the signal is changing with time. The goal of envelope tracking is to change the supply voltage according to the momentary voltage swing of the signal, such that the supply voltage will be able to support the swing without compressing the signal. If the voltage supply regulator is highly efficient, the power amplifier is maintained at its peak efficiency and the overall efficiency of the wireless transceiver is improved.

However, the current implementations of envelope tracking systems have limited usefulness in wide band applications, such as WiFi, (IEEE 802.11-2007), Worldwide Interoperability for Microwave Access (WiMAX) (IEEE 802.16e-2005) and WCDMA ((Third Generation Partnership Project 3GPP), TS 25.2B Version 3.2.0 Mar. 2000), because of the need to achieve a wide bandwidth supply regulator on one hand with high efficiency and relatively low supply ripple on the other hand. The low ripple is needed to achieve a clean spectrum with low spurs at the output of the power amplifier.

### BRIEF DESCRIPTION OF THE DRAWINGS

FIG. 1 is a schematic depiction in accordance with one embodiment;

FIG. 2 is a more detailed depiction of the envelope tracking core in accordance with one embodiment;

FIG. 3 is a graph of the signal envelope momentary power at the output of the power amplifier and supply voltage versus time, with the supply tracking shown in solid lines in accordance with one embodiment;

FIG. 4 is a graph of supply voltage to the power amplifier in volts versus time in arbitrary units in accordance with different embodiments, with one embodiment of the claimed invention shown in solid lines and the prior practice shown in dotted lines; and

FIG. 5 is a schematic depiction of one embodiment of the present invention.

### DETAILED DESCRIPTION

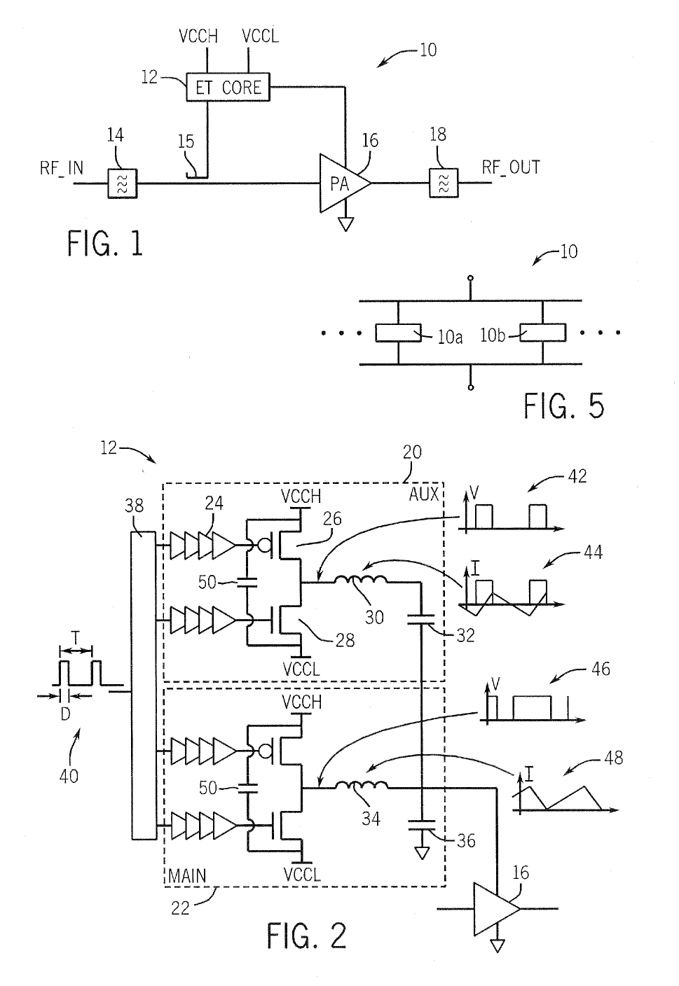

Referring to FIG. 1, a wireless transceiver 10 may include an input radio frequency filter 14, an output radio frequency filter 18, and an intervening power amplifier 16. A voltage regulating envelope tracker core 12 is coupled to supply higher voltage Vcch and lower supply voltage Vccl. In addition, the core 16 may be coupled to a sensor 15 to track the envelope of input radio frequency signal. Thus, the filter 14 has its output connected to the power amplifier input node and the filter 18 is connected to the output of the power amplifier. The envelope signal applied at the input of the envelope tracker 15 can either come from a modem or with a detected envelope signal from the driving input of the power amplifier 16.

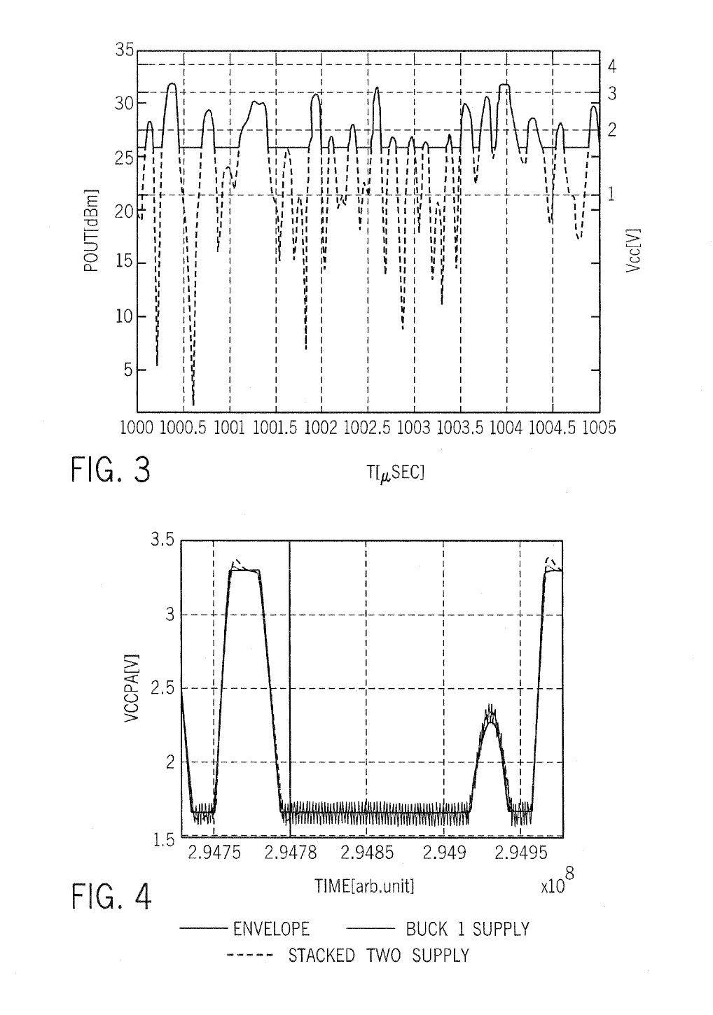

The envelope tracking output voltage is limited in range and does not follow the entire input signal to avoid chocking the power amplifier in some embodiments. Specifically, referring to FIG. 3, a simulation shows the output power of the power amplifier in decibels and supply voltage versus time in microseconds. The inventors of the present application have appreciated that it is not necessary to track the entire voltage swing, but, in fact, only a limited portion of the swing may be tracked and still get good results. Namely, if at least ten decibels of the power swing is tracked, good results can be achieved in some embodiments. In some embodiments, only about six decibels of tracking may be needed. Thus, as shown, only the solid line portion (of about 6 dBm) of the entire voltage and power output of the power amplifier, shown in dotted lines, is tracked in one embodiment. As a result, voltage tracking may then be limited to a limited voltage range determined by the more limited output power range. Typically, this is from Vcc to 0.5 Vcc.

Referring to FIG. 2, a switching power supply modulator topology for one embodiment of an envelope tracker core 12 is depicted. It is similar to conventional buck switching supply regulators, except that, in effect, two stacked buck modulators 20 and 22 are provided, each connected to a non-overlap 38 that receives the signal 40 from the sensor 15. Each buck switching supply modulator 20 or 22 is connected to the higher supply voltage Vcch and the lower supply voltage Vccl.

A buck switching supply modulator conventionally includes drivers 24 and an inverter including a PMOS transistor 26 over an NMOS transistor 28 and an output inductor 30. The output inductor 30 is coupled to a capacitor 32 and to capacitor 36 coupled to the main buck switching supply modulator 22. The output from the stacked buck switching supply modulators is coupled to the power amplifier 16, as indicated in FIG. 1 as well.

In some embodiments, a distributed capacitance 50 may be inserted between the high and low supply voltages of the supply modulators 20 and 22. In some embodiments, the distributed capacitance 50 may be a few nanoFarads and have very low equivalent series inductance (ESL). It is important to keep the inductance as low as possible since otherwise a large supply drop and ripple at the switches' supply nodes may result that can degrade circuit performance and efficiency.

As shown in FIG. 2, the output 42 or 46 of the inverter including transistors 26 and 28 is provided to the inductor 30 in the case of modulator 20 and to the inductor 34 in the case of the modulator 22. The sawtooth current waveform 44 on the auxiliary modulator 20 may be entirely AC with no DC component, whereas the sawtooth waveform 48 of the modulator 22 may also include a DC component. Although the two signals are combined at the output, the ripples cancel because they are in opposite phase and the ripples are entirely AC. Therefore, the DC component on the current signal of the main modulator 22 does not affect the cancellation.

The non-overlap circuit 38 ensures that both transistors 26 and 28 of the same modulator 20 or 22 are never on at the same time in some embodiments. Thus, the circuit 38 provides a control that ensures that once one transistor of each inverter turns completely off before the other transistor of the inverter turns on. This prevents lower and higher supply voltages from being connected together.

In some embodiments, the envelope tracking switching supply regulator topology enjoys both wide spectrum and high efficiency. Instead of using a single supply, the design includes two supplies, one higher than the other. The auxiliary AC coupled supply modulator 20 is added on top of the original main supply modulator 22. The distributed capacitance 50 is an on-chip distributed capacitance between supplies used to improve the switching regulator efficiency.

The higher supply voltage (Vcch) may be the same voltage used in conventional buck switching regulators used for envelope tracking, while the lower supply voltage (Vccl) may be a voltage, already available within the system, typically used for analog and digital circuits. In general, the lower supply voltage can be achieved using a regular low bandwidth buck converter having a bandwidth of approximately 200 kiloHertz that can be implemented today with 90 to 95 percent efficiency. For example, the lower supply voltage may be about half the higher supply voltage. Also, due to its low bandwidth, it can have very low ripple. Another option, relevant mainly for battery driven devices with low supply voltages, is to use a low bandwidth boost converter to generate the higher supply voltage.

The use of two supply voltages relaxes the voltage head room on the switching regulator, allowing the use of thin gate, fast transistors instead of thick gate transistors in some embodiments. This may improve the on resistance and may reduce the load capacitance to the drivers, thereby reducing both the dynamic switching losses and the resistive losses through the switches in some embodiments.

Furthermore, since all driving stages work between the higher and lower supply voltages, the swing at the circuit nodes is reduced from the higher supply voltage to the delta between the higher and lower supply voltages. Since the dynamic losses of switching digital circuits are proportional to the square of the swing, the dynamic losses are gradually reduced in some embodiments. In one embodiment, the lower supply voltage may be half the higher supply voltage, which results in dynamic losses being reduced by a factor of four in some embodiments. For example, the higher supply voltage may be 3.3 volts, while the lower supply voltage is 1.7 volts, as one example.

As shown in FIG. 4, the effect of the stacked modulators with two supply voltages is that the extensive ripples on the low end of the supply voltage range are substantially eliminated, as are the less substantial ripples on the high end of the voltage range. This is because the need for switching is reduced or eliminated as a result of having two voltage supplies. When either the lower or higher voltage supply is needed, there is no switching, in some embodiments, in the envelope tracking regulator. Instead, the proper voltage supply (e.g. higher or lower supply voltage) is simply connected. There is no need to switch between higher and lower voltages for the times needed to produce the desired voltage level in some embodiments. At the intermediate supply voltages where switching may occur, ripple is still counteracted by combining the ripples of opposite polarity from the two modulators, which effectively cancel one another.

The auxiliary supply modulator 20 may be driven with complementary signals (indicated at 42 and 46) to the main supply modulator 22. While the main supply modulator 22 inductor 34 carries the DC current sawtooth current ripple at the switching frequency (indicated at 48), the auxiliary modulator inductor carries zero DC current and sawtooth current ripple (indicated at 44) with the opposite direction of the ripple current in the main modulator inductor, as shown in the voltage and current over time curves inserted in FIG. 2. As a result, the ripple currents flowing into the load and capacitance are approximately canceling each other, resulting in only a very small ripple at the supply node.

Referring next to FIG. 5, a relatively high distributed capacitance with low ESL can be achieved by forming the envelope tracking supply modulator 10, especially the inverters (i.e. transistors 26 and 28) and distributed capacitances 50, as a plurality of repeating modules, each being identical to one another, those modules being connected in parallel. Transistors 26 and 28 and capacitances 50, for example, may be scaled by the number of modules, to collectively provide the needed operation. By keeping the parasitic or ESL inductance low, the ripple currents may be moderated, if not substantially eliminated, while generating distributed capacitance.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

A similar approach can also be used for envelope elimination and restoration systems (EER) for wideband signals. A class AB power amplifier may be replaced with a switch mode class E or class D power amplifier.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
controlling power consumption of a power amplifier in a wireless transceiver using an envelope tracker with stacked buck switching supply modulators, each having two different supply voltages.

2. The method of claim 1 including tracking less than 10 dB of power amplifier output power.

3. The method of claim 1 including providing a first supply voltage and a second supply voltage to each of the stacked switching supply modulators, the first supply voltage being twice the second supply voltage.

4. The method of claim 1 including a plurality of repeating, envelope tracking modules between said two voltage supplies.

5. The method of claim 1 including AC coupling the two stacked buck switching supply modulators.

6. The method of claim 1 including driving one of said supply modulators with a signal complementary to the signal driving the other of said modulators.

7. The method of claim 1 including providing an inductor on each of said modulators, one of said inductors carrying zero DC current and sawtooth current ripple with the opposite direction of the ripple current in the other of said inductors.

8. A power amplifier comprising:
an envelope tracker including a first switching supply modulator and a second switching supply modulator stacked on said first switching supply modulator;
a first voltage supply for said modulators; and
a second voltage supply for said modulators, said second voltage supply being lower than said first voltage supply.

9. The power amplifier of claim 8 wherein said envelope tracker to track less than 10 decibels of power amplifier output power.

10. The power amplifier of claim 8 including a plurality of repeating, identical envelope tracking modules and distributed capacitance.

11. The power amplifier of claim 8 wherein said modulators to generate ripple currents of opposite polarity which are combined and canceled.

12. The power amplifier of claim 8 wherein said switching supply modulators are buck switching supply modulators.

13. A power amplifier comprising:
an envelope tracker including a stacked switching supply modulator, said envelope tracker tracking less than 10 decibels of the power output of said amplifier; and
at least two voltage supplies for said envelope tracker.

14. The power amplifier of claim 13 including a plurality of identical modules coupled in parallel and distributed capacitance between said two voltage supplies.

15. The power amplifier of claim 13 wherein said modulators to generate ripple currents of opposite polarity which are combined and canceled.

16. The power amplifier of claim 13 wherein said switching supply modulators are buck switching supply modulators.

17. The power amplifier of claim 13 wherein one voltage supply has a higher voltage than the other.

18. The power amplifier of claim 17 wherein one voltage supply is about half the voltage as the other voltage supply.

19. The power amplifier of claim 13 wherein said modulators are AC coupled.

20. The power amplifier of claim 13 wherein said modulators are driven by complementary signals.
